(19) United States
(12) Patent Application Publication
(10) Pub. No.: US 2008/0149487 A1
(43) Pub. Date: Jun. 26, 2008

(54) Via Plating Method of System in Package and System Thereof

(76) Inventor: MIN HYUNG LEE, Cheongjoo-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/863,364

(22) Filed: Sep. 28, 2007

(30) Foreign Application Priority Data
Dec. 23, 2006 (KR) 10-2006-0133251

(51) Int. Cl. H01L 21/288; C25D 5/02

(52) U.S. Cl. 205/123; 204/242

(57) ABSTRACT

A via plating system and method are provided. A preprocessing procedure is performed such that a pre-wetting solution is absorbed into a via hole, forming a wetting layer thereon. A plating process is then performed to form a plating layer inside the via hole. The preprocessing procedure to form the wetting layer improves the absorbing characteristics inside the via hole, allowing the plating layer to be more effectively formed.

### CROSS-REFERENCE TO RELATED APPLICATION

The present application claims the benefit under 35 U.S.C. §119 of Korean Patent Application No. 10-2006-0133251, filed Dec. 23, 2006, which is hereby incorporated by reference in its entirety.

### BACKGROUND

In order to produce complicated circuits in semiconductor devices, the technique of stacking various semiconductor chips is often used.

The method of stacking various kinds of semiconductor chips in a wafer state and connecting them through a via is typically referred to as a system in package (SIP).

A SIP technique generally stacks various chips vertically in order to minimize the amount of space taken up by a semiconductor device.

The core technique of the SIP is the via forming method for interconnecting between the chips. In particular, in order to connect the chips, it is often required to form very deeps vias, with depths of 100 μm or more.

In order to gap-fill deep vias, a copper (Cu) plating method, such as an electroplating method, is often used.

However, when using Cu plating to gap-fill a deep via, it is often difficult to diffuse Cu ions to the inside of the deep via. This leads to a plating speed that is often very slow and common formation of voids in the via.

Thus, there exists a need in the art for an improved via plating system and method.

### BRIEF SUMMARY

Embodiments of the present invention provide a via plating system and method. A wetting layer can be formed inside a via hole during a preprocessing procedure prior to a plating process. The absorbing characteristics can be improved, leading to more effective forming of a plating layer.

In an embodiment, a via plating system can comprise a preprocessing device for providing a pre-wetting solution to a via hole on a semiconductor substrate and a plating device for forming a plating layer on the semiconductor substrate including the via hole.

A via plating method according to an embodiment comprises: forming a seed layer on a semiconductor substrate provided with a via hole; forming a wetting layer by providing a pre-wetting solution to the via hole; and forming a plating layer on the wetting layer.

### BRIEF DESCRIPTION OF THE DRAWINGS

FIGS. 1 to 4 are cross-sectional views showing a via plating method according to an embodiment of the present invention.

FIGS. 5 and 6 are views showing a preprocessing device of a via plating system according to an embodiment of the present invention.

FIG. 7 is a view showing a plating device of a via plating system according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

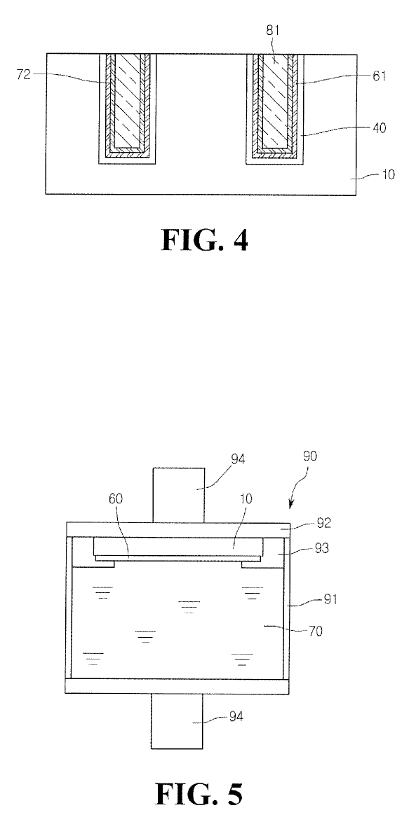

FIGS. 5 to 7 show devices used in a via plating system according to an embodiment of the present invention.

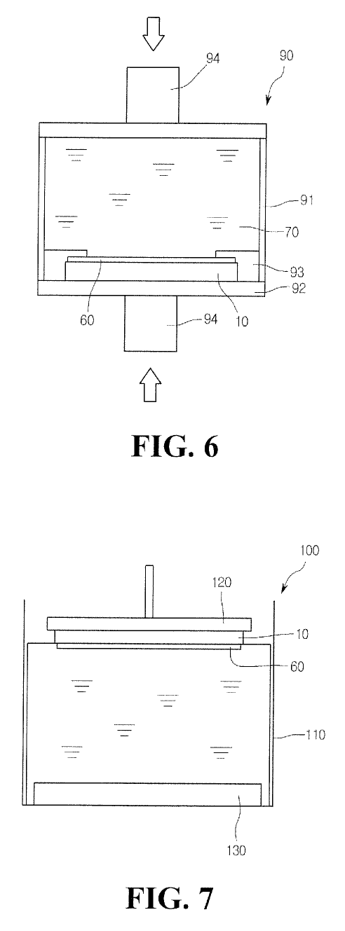

In an embodiment, the via plating system can include the use of a preprocessing device 90 (see e.g. FIGS. 5 and 6) and a plating device 100 (see e.g. FIG. 7).

Referring to FIG. 5, the preprocessing device 90 can comprise a pre-wet chamber 91, a pressing part 94, and a sealing part 93.

The pre-wet chamber 91 can be used to perform a preprocessing procedure on a semiconductor substrate 10.

A holder 92 can be provided on the upper surface of the pre-wet chamber 91 and can fix the semiconductor substrate 10 in place.

The inside of the pre-wet chamber 91 can be filled with a pre-wetting solution 70, which can smoothly form a wetting layer on a via hole provided on the semiconductor substrate 10 to improve the absorbing characteristics of the via hole. For example, the pre-wetting solution 70 can be deionized (DI) water.

The DI water can be in a state such that effectively all ions have been removed to give water having very few impurities, if any at all.

The pre-wetting solution 70 can be provided to the inside of the via hole of the semiconductor substrate 10 to wet the inside and outside of the pattern of the semiconductor substrate 10. Accordingly, a plating solution that can be subsequently provided during a plating process can be more efficiently absorbed in the via hole.

The pre-wetting solution 70 can be any appropriate solution known in the art. In an embodiment, the pre-wetting solution 70 can be a mixture of DI water and H₂SO₄ solution. In a further embodiment, the pre-wetting solution 70 can be a mixture of DI water, H₂SO₄ solution, and an organic additive.

The organic additive can be SPS (bis-(sodium-sulfopropyl)-disulfide), 3-Mercapto-1-propanesulfonic acid, polyethylene, a polypropylene glycol, polyoxyethylene lauryl ether, polyethylene oxide, alkoxylated beta-naphthol, an alkyl naphthalene sulphonate, soluble polyimine, polyamide, sulfopropylated polyethylene imine, or any combination thereof.

The sealing part 93 can be used to seal the semiconductor substrate 10 and the pre-wet chamber 91.

The pressing part 94 can apply pressure into the pre-wet chamber 91 to help provide the pre-wetting solution 70 of the pre-wet chamber 91 into the inside of the via hole of the semiconductor substrate 10.

Referring to FIG. 7, the plating device 100 can comprise an electrolyzer 110, a copper electrode 130, and a wafer electrode 120.

The inside of the electrolyzer 110 can be filled with electrolyzing solution.

The copper electrode 130 can be connected to a positive (+) electrode of a power supply and arranged in the electrolyzer 110.

The wafer electrode 120 can be arranged to be opposed to the copper electrode 130 and can be connected to a negative (−) electrode of a power supply. The wafer electrode can also be used to fix the semiconductor substrate 10 in place.

A via hole plating method that can use the preprocessing device 90 and plating device 100 described above will now be described.

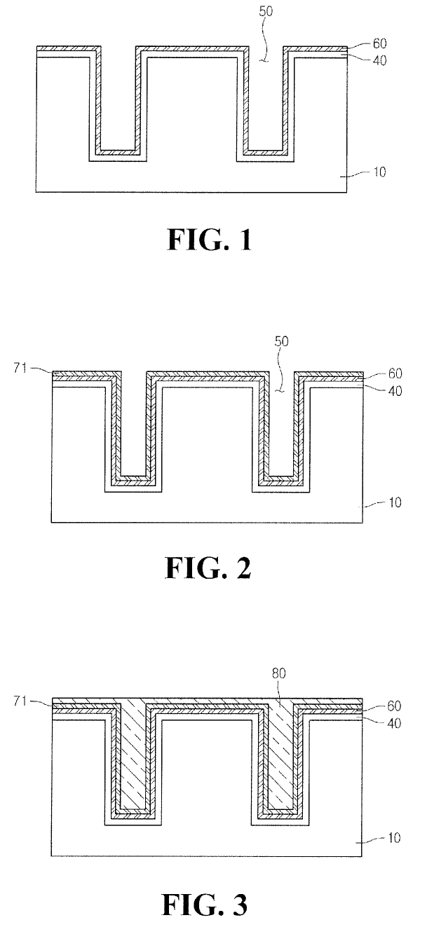

Referring to FIG. 1, a via hole 50 can be formed by patterning a semiconductor substrate 10. The via hole 50 can be a deep via hole.

An insulating layer 40 can be formed on the semiconductor substrate 10 including the via hole 50.

In an embodiment, a barrier layer (not shown) can be formed on the insulating layer 40 to help inhibit electromigration of ions into regions around the via hole 50.

A seed layer 60 can be formed on the insulating layer 40. The seed layer 60 can be formed by any appropriate method known in the art, for example, chemical vapor deposition (CVD) or a sputtering method.

A preprocessing procedure performed in a preprocessing device 90 and a plating process performed in a plating device 100 can be used to form a copper plating layer.

Referring again to FIG. 5, the semiconductor substrate 10 including the via hole 50 and the seed layer 60 can be provided to the pre-wet chamber 91 of the preprocessing device 90 and fixed on the holder 92 of the pre-wet chamber 91.

A pre-wetting solution 70 can be provided to the pre-wet chamber. For example, the pre-wetting solution 70 can be DI water, a mixture of DI water and H₂SO₄ solution, or a mixture of DI water, H₂SO₄ solution, and an organic additive.

The semiconductor substrate 10 fixed on the holder 92 can be positioned such that its surface including the via hole 50 and seed layer 60 contacts the pre-wetting solution 70.

Referring to FIG. 6, in one embodiment, the pre-wet chamber 91 can be rotated by 180° such that the semiconductor substrate can be on the opposite side of the pre-wet chamber 91 from the original position of the holder 92.

The rotation of the pre-wet chamber 91 can be performed to remove bubbles that may be present inside the via hole 50 of the semiconductor substrate 10. If the pre-wet chamber 91 is rotated, the semiconductor substrate 10 is also rotated such that the surface of the semiconductor substrate 10 with the via hole 50 is positioned to face the original position of the holder 92 of the pre-wet chamber 91. Then, any bubbles that may be present in the via hole 50 can be removed due to a pressure difference.

The sealing part 93 can be used to seal the semiconductor substrate 10 and the pre-wet chamber 91. The pressing part 94 can be used to apply pressure to the pre-wet chamber 91.

The pre-wetting solution 70 can infiltrate into the via hole 50 of the semiconductor substrate 10.

In an embodiment, the pressure applied to the pre-wet chamber 91 by the pressing part 94 is from about 0.1 psi to about 500 psi.

In an embodiment, the preprocessing procedure can be performed for a period of time of about 1 second to about 500 seconds in order to inhibit possible corrosion of the seed layer 60.

Referring to FIG. 2, the pre-wetting solution 70 can be absorbed into the via hole 50 to form a wetting layer 71.

The semiconductor substrate 10 can then be provided to the plating device 100 to perform a plating process.

In an embodiment, the semiconductor substrate 10 can be moved from the preprocessing device 90 to the plating device 100 within a period of time of less than about 5 minutes. In a further embodiment, the semiconductor substrate 10 can be moved from the preprocessing device 90 to the plating device 100 within a period of time of about 1 minute to about 5 minutes. A period of time of less than 5 minutes can help inhibit corrosion on the seed layer 60.

The semiconductor substrate 10 can be provided to the electrolyzer 110 where plating solution can be received. Then, voltage can be applied to the semiconductor substrate 10 and the copper electrode 130 to form a copper plating layer 80 on the semiconductor substrate 10 including the via hole 50.

Referring to FIG. 3, the wetting layer 71 helps the plating solution absorb onto and copper ions diffuse into the via hole 50. The generation of a void in the via can be inhibited by the wetting layer 71 as the copper plating layer 80 is formed.

Referring to FIG. 4, a planarization process on the semiconductor substrate 10 provided with the copper plating layer 80 can be performed to form a via 81. The planarization process on the copper plating layer 80 can be any appropriate method known in the art, for example, chemical mechanical polishing (CMP) using the upper surface of the semiconductor substrate 10 as an etching stop layer.

The planarization can be used to form the seed pattern 61, the wetting pattern 72, and the via 81 on the via hole 50 of the semiconductor substrate 10. In embodiments of the present invention, the wetting layer formed by a pre-wetting solution can improve the absorption of the plating layer to be formed in the via hole of the semiconductor substrate. The wetting layer can be formed during a preprocessing procedure.

Also, diffusion of copper ions during the plating process can also be improved by the wetting layer. This can further improve absorption of the plating solution and help inhibit the generation of void.

Moreover, a gap-fill can easily be performed when using the wetting layer according to embodiments of the present invention, even on a deep via with a depth of about 100 μm or more. This can lead to an improved yield of a semiconductor device. Accordingly, embodiments can be used for providing via formation for SIPs.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A via plating system, comprising:
a preprocessing device including a pre-wetting solution; and
a plating device for forming a plating layer on a semiconductor substrate.

2. The via plating system according to claim 1, wherein the preprocessing device comprises:
a pre-wet chamber including the pre-wetting solution;
a holder on a surface of the pre-wet chamber for fixing a semiconductor substrate in place;
a sealing unit for sealing the pre-wet chamber; and
a pressing unit for applying pressure into the pre-wet chamber.

3. The via plating system according to claim 1, wherein the pre-wetting solution comprises deionized (DI) water.

4. The via plating system according to claim 3, wherein the pre-wetting solution further comprises H₂SO₄ solution.

5. The via plating system according to claim 4, wherein the pre-wetting solution further comprises an organic additive.

6. The via plating system according to claim 5, wherein the organic additive is SPS (bis-(sodium-sulfopropyl)-disulfide), 3-Mercapto-1-propanesulfonic acid, polyethylene, a polypropylene glycol, polyoxyethylene lauryl ether, polyethylene oxide, alkoxylated beta-naphthol, an alkyl naphthalene sulphonate, soluble polyimine, polyamide, sulfopropylated polyethylene imine, or any combination thereof.

7. The via plating system according to claim 2, wherein the pre-wet chamber is capable of being rotated by 180°, such that the semiconductor substrate fixed on the holder faces the opposite direction after the pre-wet chamber is rotated.

8. The via plating system according to claim 1, wherein the plating device comprises:
an electrolyzer including an electrolyzing solution;
a copper electrode provided in the electrolyzer; and
a wafer electrode provided in the electrolyzer and spaced apart from the copper electrode, wherein the wafer electrode fixes the semiconductor substrate in place facing the copper electrode.

9. The via plating system according to claim 8, further comprising a power supply, wherein the copper electrode is connected to a positive electrode of the power supply, and wherein the wafer electrode is connected to a negative electrode of the power supply.

10. A via plating method, comprising:
forming a seed layer on a semiconductor substrate provided with a via hole;
forming a wetting layer on the semiconductor substrate, including in the via hole, by providing a pre-wetting solution; and
forming a plating layer on the semiconductor substrate including in the via hole provided with the wetting layer.

11. The via plating method according to claim 10, wherein forming a wetting layer comprises:
providing the semiconductor substrate to a chamber including the pre-wetting solution;
sealing the chamber; and
applying pressure to the inside of the pre-wet chamber.

12. The via plating method according to claim 11, further comprising rotating the chamber by 180° before applying pressure to the inside of the pre-wet chamber.

13. The via plating method according to claim 11, wherein the pressure applied to the chamber is about 0.1 psi to about 500 psi.

14. The via plating method according to claim 11, wherein the total time the semiconductor substrate is in the chamber is about 1 second to about 500 seconds.

15. The via plating method according to claim 11, wherein the pre-wetting solution comprises deionized (DI) water.

16. The via plating method according to claim 15, wherein the pre-wetting solution further comprises H₂SO₄ solution.

17. The via plating method according to claim 16, wherein the pre-wetting solution further comprises an organic additive.

18. The via plating method according to claim 17, wherein the organic additive is SPS (bis-(sodium-sulfopropyl)-disulfide), 3-Mercapto-1-propanesulfonic acid, polyethylene, a polypropylene glycol, polyoxyethylene lauryl ether, polyethylene oxide, alkoxylated beta-naphthol, an alkyl naphthalene sulphonate, soluble polyimine, polyamide, sulfopropylated polyethylene imine, or any combination thereof.

19. The via plating method according to claim 11, wherein the period of time between the completion of forming the wetting layer and the initiation of forming the plating layer is no more than 5 minutes.
